(19) United States
(12) Patent Application Publication
(10) Pub. No.: US 2025/0254887 A1
(43) Pub. Date: Aug. 7, 2025

(54) MEMORY DEVICE

(71) Applicant: Powerchip Semiconductor Manufacturing Corporation, Hsinchu (TW)

(72) Inventors: Hsin-Hsueh Lin, Hsinchu (TW); Tseung-Yuen Tseng, Hsinchu (TW)

(73) Assignee: Powerchip Semiconductor Manufacturing Corporation, Hsinchu (TW)

(21) Appl. No.: 18/639,973

(22) Filed: Apr. 19, 2024

(30) Foreign Application Priority Data
Feb. 7, 2024 (TW) 113105146

(51) Int. Cl. H10B 53/30

(52) U.S. Cl. CPC H10B 53/30

(57) ABSTRACT

The present disclosure provides a memory device including a plurality of memory cells. Each memory cell includes a bottom electrode disposed on the substrate, a ferroelectric layer disposed on the bottom electrode, a barrier layer disposed on the ferroelectric layer, and a top electrode disposed on the barrier layer. The barrier layer is interposed between the top electrode and the ferroelectric layer, and the thickness of the barrier layer is less than the thickness of the ferroelectric layer.

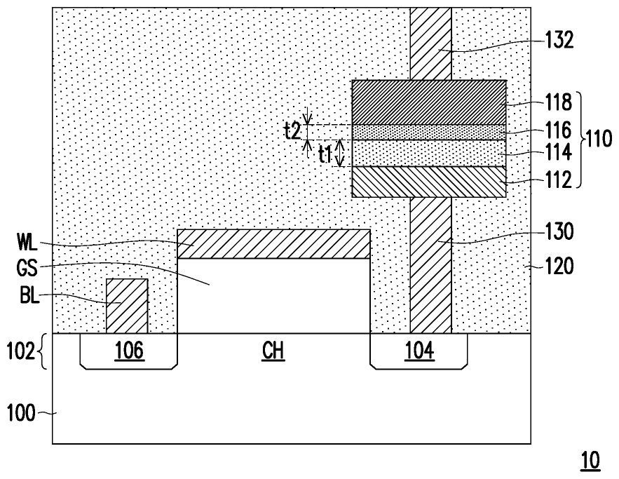

### CROSS-REFERENCE TO RELATED APPLICATION

This application claims the priority benefit of Taiwan application serial no. 113105146, filed on Feb. 7, 2024. The entirety of the above-mentioned patent application is hereby incorporated by reference herein and made a part of this specification.

### BACKGROUND

### Technical Field

The present invention relates to a semiconductor device, and in particular to a memory device.

### Description of Related Art

Ferroelectric tunnel junction (FTJ) was first proposed in 1996. It was the subject of extensive research due to its potential applications in high-density data storage, non-volatile memory, and neuromorphic computing. The basic structure of an FTJ consists of two metal electrodes separated by a thin layer of ferroelectric material. When a voltage is applied across the electrodes, the polarization of the ferroelectric material can be switched, causing a change in the tunneling current between the electrodes. This change in current can be used to store and retrieve information.

In the memory device that uses the FTJ (e.g., ferroelectric random-access memory), the memory device can exhibit more multilevel states by applying more pulse voltages with different amplitudes as the on/off ratio of the memory device is larger. In other words, the larger the on/off ratio is, the higher the storage density can be achieved. However, as the electronic devices continue to develop toward compact size and high performance, the existing FTJ memory devices may not be able to meet the needs of the electronic devices in the current or future.

### SUMMARY

The invention provides a memory device in which the FTJ structure included in the memory cell is designed to include a barrier layer interposed between the top electrode and the ferroelectric layer. The barrier layer can be served as a tunneling barrier so that the current leakage caused by a tunneling current leaking to the insulating layer can be reduced effectively, as such the on/off ratio of the FTJ structure can be enhanced by reducing the off-current of the memory device.

An embodiment of the present invention provides a memory device including a plurality of memory cells in which each of the memory cells includes a bottom electrode disposed on a substrate, a ferroelectric layer disposed on the bottom electrode, a barrier layer disposed on the ferroelectric layer, and a top electrode disposed on the barrier layer. The barrier layer is interposed between the top electrode and the ferroelectric layer, and a thickness of the barrier layer is less than a thickness of the ferroelectric layer.

In some embodiments, the barrier layer includes magnesium oxide (MgO).

In some embodiments, the ferroelectric layer includes hafnium zirconium oxide (HfZrO₂, HZO).

In some embodiments, a material of the bottom electrode is different from a material of the top electrode.

In some embodiments, the bottom electrode includes titanium nitride (TiN) and the top electrode includes tungsten (W).

In some embodiments, the thickness of the ferroelectric layer is about 6 nm.

In some embodiments, the thickness of the barrier layer is less than or equal to about 1 nm.

In some embodiments, the thickness of the barrier layer is less than or equal to about 0.5 nm.

In some embodiments, the memory device further includes a gate structure disposed on the substrate and a source and a drain respectively disposed in the substrate at opposite sides of the gate structure. The drain is electrically connected to the bottom electrode, and the source is electrically connected to a bit line.

In some embodiments, the bottom electrode directly contacts the ferroelectric layer, and the barrier layer directly contacts the top electrode and the ferroelectric layer.

Based on the above, in the aforementioned memory device, the FTJ structure included in the memory cell is designed to include a barrier layer interposed between the top electrode and the ferroelectric layer. The barrier layer can be served as a tunneling barrier so that the current leakage caused by a tunneling current leaking to the insulating layer can be reduced effectively, as such the on/off ratio of the FTJ structure can be enhanced by reducing the off-current of the memory device.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGURE shows a schematic cross-sectional view illustrating a memory device according to an embodiment of the present invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

FIGURE shows a schematic cross-sectional view illustrating a memory device according to an embodiment of the present invention.

In some embodiments, the semiconductor device 10 may include a plurality of memory cells 110, and each of the memory cells 110 may include a bottom electrode 112 disposed on the substrate 100, a ferroelectric layer 114 disposed on the bottom electrode 112, and a barrier layer 116 disposed on the ferroelectric layer 114, and a top electrode 118 disposed on barrier layer 116. The barrier layer 116 is interposed between the top electrode 118 and the ferroelectric layer 114, so that the current leakage caused by a tunneling current leaking to the insulating layer can be reduced effectively, as such the on/off ratio of the FTJ structure can be enhanced by reducing the off-current of the memory device. In addition, the barrier layer 116 interposed between the top electrode 118 and the ferroelectric layer 114 can improve the interface quality between the top electrode 118 and the ferroelectric layer 114, so that the current leakage caused by the charge scattering or the interface defects can be reduced and therefore the on/off ratio of the FTJ can be enhanced.

The substrate 100 may include a semiconductor substrate or a semiconductor-on-insulator (SOI) substrate. The semiconductor materials in the semiconductor substrate or in the SOI substrate may include an element semiconductor, an alloy semiconductor, or a compound semiconductor. For example, the element semiconductor may include Si or Ge. The alloy semiconductor may include SiGe, SiGeC, or the like. The compound semiconductor may include SiC, III-V semiconductor materials, or II-VI semiconductor materials. The III-V semiconductor materials may include GaN, GaP, GaAs, AlN, AIP, AlAs, InN, InP, InAs, GaNP, GaNAs, GaPAs, AlNP, AlNAs, AlPAs, InNP, InNAs, InPAs, GaAlNP, GaAINAs, GaAlPAs, GaInNP, GalnNAs, GalnPAs, InAINP, InAINAs, or InAlPAs. The II-VI semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type complementary to the first conductivity type. For example, the first conductivity type may be p-type, whereas the second conductivity type may be n-type.

The bottom electrode 112 may include conductive materials. For example, the bottom electrode 112 may include materials such as copper (Cu), aluminum (Al), zirconium (Zr), titanium (Ti), titanium nitride (TiN), tungsten (W), tantalum (Ta), tantalum nitride (TaN), molybdenum (Mo), ruthenium (Ru), palladium (Pd), platinum (Pt), cobalt (Co), nickel (Ni), iridium (Ir), and the likes.

The ferroelectric layer 114 may include a ferroelectric material. For example, the ferroelectric layer 114 may include a ferroelectric material such as HfₓZr₁₋ₓO₂ (HZO), where x is between 0 and 1. When the ferroelectric layer 114 is HZO, the thickness t1 of the ferroelectric layer 114 is about 6 nm. In this case, if the thickness of the ferroelectric layer 114 is less than 6 nm (e.g., 3 nm), the memory cell 110 may not be able to exhibit the ferroelectric property, and if the thickness of the ferroelectric layer 114 is greater than 6 nm (e.g., 8.5 nm), the on-current of the memory cell 110 becomes smaller and thereby the on/off ratio of the FTJ structure is decreased.

The barrier layer 116 may include a material having a wide bandgap, such as magnesium oxide (MgO), to adjust the energy band of the FTJ structure, so that the energy band of the FTJ structure can be adjusted leading to a significant difference in the band structure after applying opposite polarity voltages, consequently, increases the on/off ratio of the FTJ structure. The thickness t2 of the barrier layer 116 is smaller than the thickness t1 of the ferroelectric layer 114. As such, the barrier layer 116 can have an effect as severing a tunneling barrier (reducing the off-current of the memory device) while the on-current of the memory device is unaffected since the tunneling barrier is relative thin. In some embodiments, the thickness t2 of the barrier layer 116 is less than or equal to about 1 nm. In some alternative embodiments, the thickness t2 of the barrier layer 116 is less than or equal to about 0.5 nm.

In the case where the ferroelectric layer 114 is a HZO layer having a thickness t1 of 6 nm and the barrier layer 116 is a MgO layer having a thickness t2 of 0.5 nm, the on/off ratio of the memory cell 110 is about 32.

The top electrode 118 may include conductive materials. For example, the top electrode 118 may include materials such as copper (Cu), aluminum (Al), zirconium (Zr), titanium (Ti), titanium nitride (TiN), tungsten (W), tantalum (Ta), tantalum nitride (TaN), molybdenum (Mo), ruthenium (Ru), palladium (Pd), platinum (Pt), cobalt (Co), nickel (Ni), iridium (Ir), and the likes.

In some embodiments, the material of the bottom electrode 112 may be different from the material of the top electrode 118. In this way, the asymmetric electrodes are configured to offset the internal bias arising from the barrier layer 116, so that it may be possible to counterbalance the inherent bias and achieve desired device performance. For example, the bottom electrode 112 may include titanium nitride (TiN), and the top electrode 118 may include tungsten (W).

In some embodiments, the bottom electrode 112 directly contacts the ferroelectric layer 114, and the barrier layer 116 directly contacts the top electrode 118 and the ferroelectric layer 114.

In some embodiments, the semiconductor device 10 may further include a gate structure GS disposed on the substrate 100 and a drain 104 and a source 106 respectively disposed in the substrate 100 at opposite sides of the gate structure GS. The gate structure GS is electrically connected to a word line WL. In some embodiments, the word line WL may be disposed on the gate structure GS. The drain 104 is electrically connected to the bottom electrode 112. In some embodiments, the drain 104 may be electrically connected to the bottom electrode 112 through a conductive contact 130. The source 106 is electrically connected to a bit line BL. In some embodiments, the bit line BL is disposed on the source 106. The word line WL, the bit line BL, and the conductive contact 130 may each include conductive materials such as metals or metal alloys. The metals and the metal alloys may be, for example, Cu, Al, Ti, Ta, W, Pt, Cr, Mo, or alloys thereof.

In some embodiments, a channel CH of a transistor including the gate structure GS, the drain 104 and the source 106 may be formed in the substrate 100 below the gate structure GS and between the drain 104 and the source 106. In some embodiments, the drain 104, the source 106 and the channel CH may be formed by the following steps. Firstly, a semiconductor layer 102 may be formed on the substrate 100 (e.g., an amorphous silicon substrate or a polysilicon substrate). The semiconductor layer 102 may include the drain 104 and the source 106 in which the drain 104 and the source 106 may be formed by doping portions of the substrate 100 with a dopant having a first conductivity type or a second conductivity type. For example, the drain 104 and the source 106 may be formed by implanting dopants, such as by an ion implantation process. The channel CH of the transistor may be formed between the drain 104 and the source 106. The channel CH may be doped with dopants having different conductivity type than the dopants of the drain 104 and the source 106, such that the channel CH has a different conductivity type than the drain 104 and the source 106. In some alternative embodiments, the semiconductor layer 102 may utilize other suitable semiconductor materials such as polysilicon, amorphous silicon, or semiconducting oxides, such as InGaZnO (IGZO), indium tin oxide (ITO), InWO, InZnO, InSnO, GaOx, InOx, or the likes to form the channel CH and other non-silicon materials to form the drain 104 and the source 106.

In some embodiments, the semiconductor device 10 may further include a dielectric layer 120 disposed on the substrate 100 in which the gate structure GS, the bit line BL, the word line WL, the memory cell 110 and the conductive contact 130 may be embedded in the dielectric layer 120. The dielectric layer 120 may include dielectric materials such as oxides (e.g., silicon oxide). In some embodiments, the top electrode 118 of the memory cell 110 may be electrically connected to a wiring 132 formed thereon. The wiring 132 may be embedded in dielectric layer 120 and may include conductive materials such as metals or metal alloys. The metals and metal alloys may be, for example, Cu, Al, Ti, Ta, W, Pt, Cr, Mo or alloys thereof.

In some embodiments, the FTJ structure included in the memory cell 110 can be applied to the neuromorphic computing. For example, in biology, chemical synapses are commonly found in human brain that transmit neurotransmitters to the postsynaptic by exocytosis and diffusion. Changes in synaptic weights are also known as synaptic plasticity. When the above FTJ structure of the memory device has a greater on/off ratio, the memory device can exhibit more multilevel states corresponding to the changes in synaptic weights by applying more pulse voltages with different amplitude. Namely, the FTJ structure included in the memory cell can achieve good performance through Multi-level state characteristics to achieve changes corresponding to synaptic weights. In other words, the FTJ structure included in the memory cell 110 can effectively mimic synaptic behavior and therefore is suitable for the application in neural computing.

In summary, in the above memory device, the FTJ structure included in the memory cell is designed to include a barrier layer interposed between the top electrode and the ferroelectric layer. The barrier layer can be served as a tunneling barrier so that the current leakage caused by a tunneling current leaking to the insulating layer can be reduced effectively, as such the on/off ratio of the FTJ structure can be enhanced by reducing the off-current of the memory device.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device comprising a plurality of memory cells, wherein each of the memory cells comprises:
a bottom electrode disposed on a substrate;
a ferroelectric layer disposed on the bottom electrode;
a barrier layer disposed on the ferroelectric layer; and
a top electrode disposed on the barrier layer,
wherein the barrier layer is interposed between the top electrode and the ferroelectric layer, and a thickness of the barrier layer is less than a thickness of the ferroelectric layer.

2. The memory device of claim 1, wherein the barrier layer comprises magnesium oxide (MgO).

3. The memory device of claim 2, wherein the ferroelectric layer comprises hafnium zirconium oxide (HfZrO, HZO).

4. The memory device of claim 1, wherein a material of the bottom electrode is different from a material of the top electrode.

5. The memory device of claim 4, wherein the bottom electrode comprises titanium nitride (TiN), and the top electrode comprises tungsten (W).

6. The memory device of claim 1, wherein the thickness of the ferroelectric layer is about 6 nm.

7. The memory device of claim 6, wherein the thickness of the barrier layer is less than or equal to about 1 nm.

8. The memory device of claim 6, wherein the thickness of the barrier layer is less than or equal to about 0.5 nm.

9. The memory device of claim 1 further comprises:
a gate structure disposed on the substrate; and
a drain and a source respectively disposed in the substrate at opposite sides of the gate structure, wherein the drain is electrically connected to the bottom electrode, and the source is electrically connected to a bit line.

10. The memory device of claim 1, wherein the bottom electrode directly contacts the ferroelectric layer, and the barrier layer directly contacts the top electrode and the ferroelectric layer.
